(19) United States
(12) Patent Application Publication
(10) Pub. No.: US 2022/0130984 A1
(43) Pub. Date: Apr. 28, 2022

(54) SEMICONDUCTOR DEVICE AND METHOD OF FORMING A SEMICONDUCTOR STRUCTURE

(71) Applicant: National Central University, Taoyuan City (TW)

(72) Inventors: Yue-Ming HSIN, Taoyuan City (TW); Meng-Hsuan TSAI, Taoyuan City (TW); Chia-Jung TSAI, New Taipei City (TW); Xin-Rong YOU, Yuanlin City (TW); Chih-Wei CHEN, Hsinchu City (TW)

(21) Appl. No.: 17/082,913

(22) Filed: Oct. 28, 2020

(51) Int. Cl. H01L 29/778; H01L 29/74; H01L 29/66

(52) U.S. Cl. CPC H01L 29/7786; H01L 29/742; H01L 29/2003; H01L 29/66401; H01L 29/66462; H01L 29/66378

(57) ABSTRACT

A semiconductor device includes a substrate, a buffer layer disposed on the substrate, a barrier layer disposed on the buffer layer, a source, a drain, and a gate stack. The source, the drain, and the gate stack are disposed on the barrier layer. The gate stack includes a first epitaxial layer on the barrier layer, a second epitaxial layer on the first epitaxial layer, and a third epitaxial layer on the second epitaxial layer. The semiconductor device further includes a gate disposed on the gate stack.

### BACKGROUND OF THE INVENTION

### Field of the Invention

The present invention relates to a semiconductor device, and, in particular, to a semiconductor device of a high electron mobility transistor.

### Description of the Related Art

With the development of semiconductor technology, the market is no longer satisfied with traditional silicon transistors. In high-power applications and high-frequency applications, III-V compound semiconductors have shown the potential to replace silicon transistors. In recent years, High Electron Mobility Transistor (HEMT) made of gallium nitride (GaN) in III-V compound semiconductors has attracted particular attention.

However, a classic GaN HEMT is a depletion-mode (D-mode) device due to the two dimensional electron gas (2DEG) formed by the polarization effect. It makes the channel of GaN HEMT is belong to a normally-on status. Therefore, the threshold voltage (Vth) of GaN HEMT will be negative. As a result, an additional negative voltage is required to be applied to the gate to turn off the GaN HEMT, which will cause additional power consumption. Accordingly, the market has begun to pursue enhancement-mode (E-mode) device, that is, normally-off device.

A common method for manufacturing an enhancement-mode device is to use p-type-doped GaN to fabricate a gate stack to modify the energy band structure, such that the energy band is bent upwards and thus makes the quantum well and 2DEG disappear. In this way, the threshold voltage can be greater than 0 V (volt). However, the threshold voltage of HEMT using p-type GaN gate stack is still too low to prevent false turn on caused by surges, electromagnetic interference (EMI), noise, or voltage disturbance. In addition, HEMT using p-type GaN gate stack has limitations on the operating voltage of the gate (only about 6V), and it is difficult to increase the channel current (also referred to as drain current) by increasing the gate voltage.

### BRIEF SUMMARY OF THE INVENTION

The present disclosure provides a semiconductor device. The semiconductor device comprises a substrate; a buffer layer disposed on the substrate; a barrier layer disposed on the buffer layer; a source, a drain, and a gate stack disposed on the barrier layer; and a gate disposed on the gate stack. Wherein the gate stack comprises a first epitaxial layer over the barrier layer and a second epitaxial layer over the first epitaxial layer.

The present disclosure provides a semiconductor device. The semiconductor device comprises a substrate; a buffer layer disposed on the substrate; a barrier layer disposed on the buffer layer; a stack structure disposed on the barrier layer; an anode disposed on the stack structure; and a cathode disposed on the barrier layer, wherein the cathode surrounds the stack structure and the anode.

The present disclosure provides a method for forming a semiconductor structure. The method comprises forming a buffer layer on a substrate; forming a barrier layer on the buffer layer; forming an epitaxial structure on the barrier layer, wherein the epitaxial structure comprises a first epitaxial layer, a second epitaxial layer over the first epitaxial layer, and a third epitaxial layer over the second epitaxial layer; and forming a first semiconductor device in a first region of the semiconductor structure. The process of forming the first semiconductor device comprises performing a first etching process on the epitaxial structure to form a first gate stack from the epitaxial structure, and remove the epitaxial structure other than the first gate stack and expose the barrier layer; forming a first source and a first drain on the barrier layer; and forming a first gate on the first gate stack.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the drawings appended illustrate only typical embodiments of this disclosure and are therefore not to be considered limiting in scope, for the disclosure may apply equally well to other embodiments.

FIG. 1 shows a cross-sectional view of an intermediate stage for manufacturing a semiconductor structure, in accordance with some embodiments of the present disclosure.

FIG. 2 shows a cross-sectional view of the semiconductor structure, in accordance with some embodiments of the present disclosure.

FIGS. 3A and 3B show cross-sectional views of intermediate stages for forming a semiconductor device in the semiconductor structure, in accordance with some embodiments of the present disclosure.

FIG. 3C shows a cross-sectional view of the semiconductor device, in accordance with some embodiments of the present disclosure.

FIG. 4A shows a cross-sectional view of intermediate stage for forming a semiconductor device in the semiconductor structure, in accordance with some embodiments of the present disclosure.

FIG. 4B shows a cross-sectional view of the semiconductor device, in accordance with some embodiments of the present disclosure.

FIG. 5A shows a cross-sectional view of intermediate stage for forming a semiconductor device in the semiconductor structure, in accordance with some embodiments of the present disclosure.

FIG. 5B shows a cross-sectional view of the semiconductor device, in accordance with some embodiments of the present disclosure.

FIG. 6A shows a cross-sectional view of intermediate stage for forming a semiconductor device in the semiconductor structure, in accordance with some embodiments of the present disclosure.

FIG. 6B shows a cross-sectional view of the semiconductor device, in accordance with some embodiments of the present disclosure.

FIG. 7 shows simulating characteristic curves of drain current-gate voltage (Id-Vg) of the semiconductor devices, in accordance with some embodiments of the present disclosure.

### DETAILED DESCRIPTION OF THE INVENTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, unless specifically disclaimed, the singular includes the plural and vice versa. And when a number or a range of numbers is described with “about,” “approximate,” and the like, the term is intended to encompass numbers that are within a reasonable range including the number described, such as within +/−10% of the number described or other values as understood by person skilled in the art. In addition, the present disclosure is not limited by the illustrated ordering of acts or events, as some acts may occur in different orders and/or concurrently with other acts or events. Furthermore, not all illustrated acts or events are required to implement a methodology in accordance with the present disclosure.

The present disclosure provides a semiconductor device and manufacturing method thereof. The semiconductor device is an enhancement-mode high electron mobility transistor (HEMT). The semiconductor device has a higher threshold voltage (Vth) that can prevent false turn on caused by surge, electromagnetic interference (EMI), noise, or voltage disturbance. In addition, the semiconductor device has a larger range of operating voltage, and therefore can enhance the channel current by increasing the gate voltage and have better reliability at the same gate voltage.

The semiconductor device may be included in an integrated circuit (IC). The IC may include various other components, such as static random access memory (SRAM) and/or other logic circuits, passive devices, and active devices. The passive devices comprise resistors, capacitors, and inductors. The active devices comprise p-type field effect transistors (PFETs), n-type field effect transistors (NFETs), FinFET, metal-oxide-semiconductor field effect transistors (MOSFETs), complementary MOS (CMOS) transistors, bipolar junction transistors (BJTs), high voltage transistors, high frequency transistors, and/or other memory units.

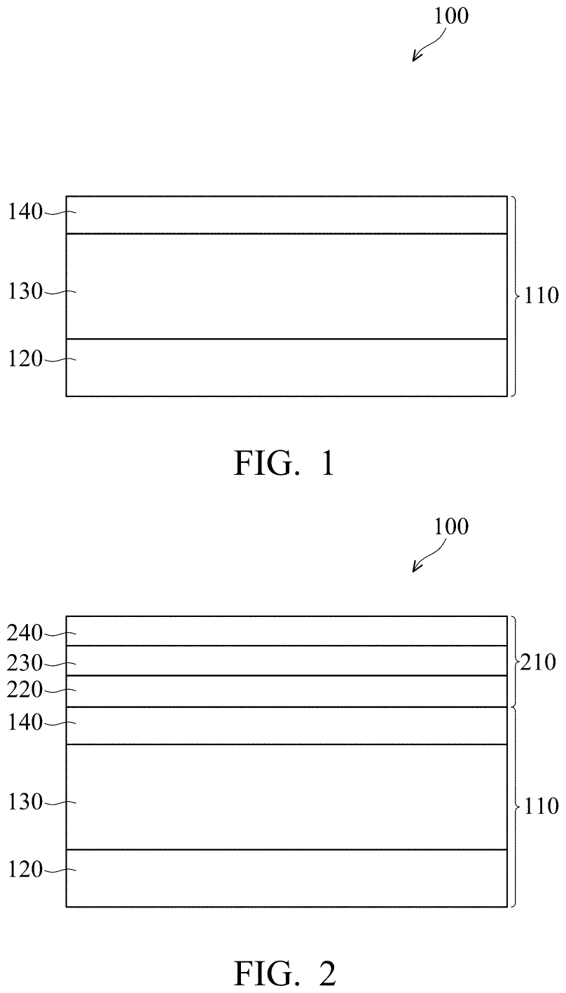

FIG. 1 shows a cross-sectional view of an intermediate stage for manufacturing semiconductor structure 100, in accordance with some embodiments of the present disclosure. In FIG. 1, epitaxial structure 110 is provided. The epitaxial structure 110 comprises substrate 120, buffer layer 130 over the substrate 120, and barrier layer 140 over the buffer layer 130. The materials of substrate 120 may be silicon (Si), silicon carbide (SiC), sapphire, gallium nitride (GaN), aluminum gallium nitride (AlGaN), aluminum nitride (AlN), gallium phosphide (GaP), gallium arsenide (GaAs), aluminum gallium arsenide (AlGaAs), or other III-V compounds.

The materials of buffer layer 130 may be GaN, AlGaN, indium gallium nitride (InGaN), aluminum indium gallium nitride (AlInGaN), or other III-V semiconductor compounds. The materials of barrier layer 140 may be GaN, AlGaN, AlN, InGaN, aluminum indium nitride (AlInN), AlInGaN, or other III-V semiconductor compounds. The energy band gap of the buffer layer 130 is less than the energy band gap of the barrier layer 140. It should be noted that, the combination and thickness of buffer layer 130 and barrier layer 140 should be able to form quantum well and two-dimensional electron gas (2DEG) between the buffer layer 130 and barrier layer 140 to form the channel of the device. For example, the thickness of the buffer layer 130 may be in a range between 3 μm (micrometer) to 5 μm, and the thickness of the barrier layer 140 may be in a range between 15 nm (manometer) to 30 nm.

In some embodiments of the present disclosure, the material of the buffer layer 130 is GaN, and the material of the barrier layer 140 is AlₓGa₁₋ₓN, wherein 0<x<1. In other embodiments, the buffer layer 130 and/or the barrier layer 140 may be a structure with multiple layers. In some embodiments, the epitaxial structure 110 may further comprise a nucleation layer (not shown). The nucleation layer can be used to compensate the mismatch of lattice between the substrate 120 and the buffer layer 130. In some embodiments, the epitaxial structure 110 may further comprise a cap layer (not shown). The cap layer can be formed on the barrier layer 140 to prevent the barrier layer 140 from oxidizing.

The buffer layer 130 may be formed on the substrate 120 and the barrier layer 140 may be formed on the buffer layer 130 by epitaxy technology. The epitaxy technology may comprise chemical vapor deposition (CVD), Low-Pressure CVD (LPCVD), Low-Temperature CVD (LTCVD), Rapid-Thermal CVD (RTCVD), plasma-enhanced CVD (PECVD), high density plasma CVD (HDPCVD), metal organic CVD (MOCVD), molecular beam epitaxy (MBE), liquid phase epitaxy (LPE), vapor phase epitaxy (VPE), atomic layer epitaxy (ALE), and a like, or combination thereof.

Please refer to FIG. 2, the epitaxial structure 210 is formed on the epitaxial structure 110. The epitaxial structure 210 comprises a first epitaxial layer 220, a second epitaxial layer 230, and a third epitaxial layer 240. The thickness of the first epitaxial layer 220, the second epitaxial layer 230, and the third epitaxial layer 240 may be in a range between about 50 nm to about 100 nm. The epitaxial structure 210 may be formed on the epitaxial structure 110 by epitaxy technology. The epitaxy technology may comprise CVD, LPCVD, LTCVD, RTCVD, PECVD, HDPCVD, MOCVD, MBE, LPE, VPE, ALE, and a like, or combination thereof.

In some embodiments, the materials of the first epitaxial layer 220 and the third epitaxial layer 240 are p-type semiconductor material, and the material of the second epitaxial layer 230 is n-type semiconductor material. In some embodiments, the first epitaxial layer 220 and the third epitaxial layer 240 are p-type-doped GaN (p-GaN), such as GaN doped by carbon, iron, magnesium, zinc, or other suitable p-type dopants. In some embodiments, the second epitaxial layer 230 is n-type-dopes GaN (n-GaN), such as GaN doped by silicon or other suitable n-type dopants. In some other embodiments, the second epitaxial layer 230 is undoped-GaN. The doping of dopants can be performed by ion-implantation process, in-situ doping epitaxial growth process, and/or other suitable technologies.

After the epitaxial structure 210 is formed, the epitaxial structure 210 will cause band bending, and thus cause the quantum well to disappear. As a result, the two-dimensional electron gas (2DEG) as the channel will also disappear. It should be noted that, in some embodiments, the band bending caused by the first epitaxial layer 220 is enough to make the quantum well disappear.

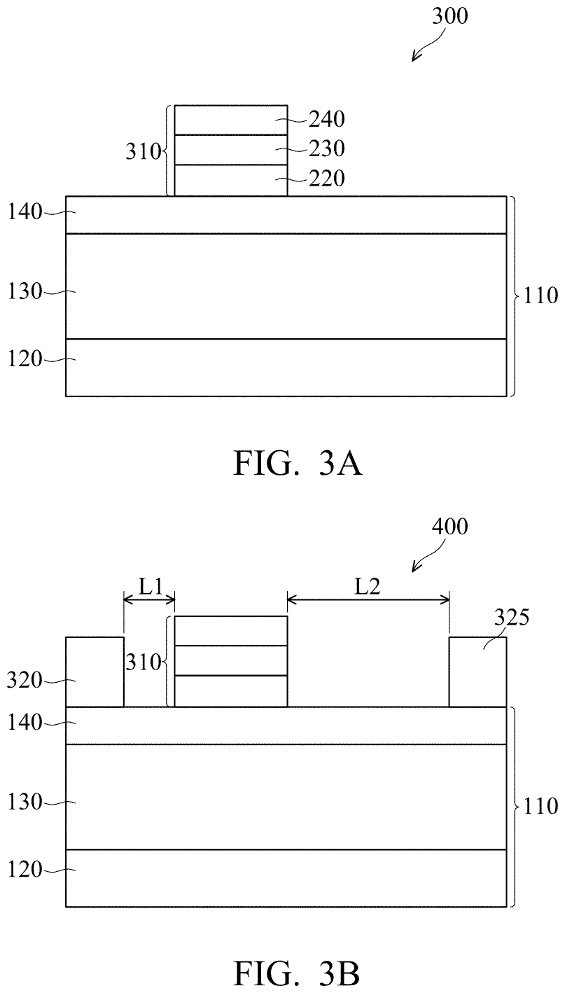

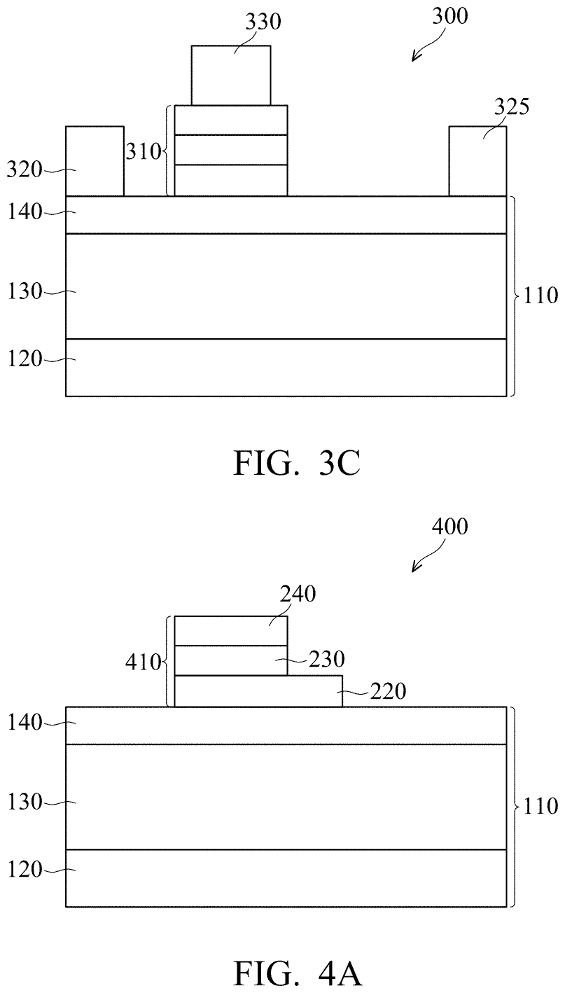

Following the process of FIG. 2, FIG. 3A shows the cross-sectional view of the intermediate stage for forming a semiconductor device 300 by utilizing the semiconductor structure 100, in accordance with some embodiments of the present disclosure. For example, the semiconductor device 300 may be formed in a first region of the semiconductor structure 100. The semiconductor device 300 may be a high electron mobility transistor (HEMT). In FIG. 3A, a gate stack 310 is formed from the epitaxial structure 210. The gate stack 310 comprises patterned first epitaxial layer 220, patterned second epitaxial layer 230, and patterned third epitaxial layer 240. Some portions of the epitaxial structure 210 can be removed by patterning process to form the gate stack 310 and exposed the portion of barrier layer 140 that is not covered by the gate stack 310. The patterning process includes suitable photolithography processes and etching processes.

In some embodiments, the photolithography processes include photoresist coating (e.g., spin-on coating), soft baking, mask aligning, exposure, post-exposure baking, developing the photoresist, rinsing, and drying (e.g., hard baking). In other embodiments, the photolithography processes may be implemented or replaced by other suitable methods, such as maskless photolithography, electron-beam writing, and ion-beam writing. In some embodiments, the etching process may include dry etching, wet etching, reactive ion etching (RIE), and/or other suitable processes.

After the gate stack 310 is formed, since the area not covered by the gate stack 310 is no longer affected by the band bending caused by the epitaxial structure 210, the quantum well reappears, and the 2DEG as the channel also appears. However, in the area under the gate stack 310, due to the band bending caused by the gate stack 310, there is still no quantum well and 2DEG.

Please refer to FIG. 3B, a source structure 320 and a drain structure 325 are formed on the barrier layer 140. In some embodiments, the source structure 320 and the gate stack 310 are separated by a first distance L1, wherein the first distance L1 is in a range between 1 μm and 3 μm. The drain structure 325 and the gate stack 310 are separated by a second distance L2, wherein the second distance L2 is in a range between 4 μm and 18 μm. The materials of the source structure 320 and the drain structure 325 may include but not limit to: aluminum (Al), copper (Cu), gold (Au), silver (Ag), tungsten (W), titanium (Ti), tantalum (Ta), nickel (Ni), cobalt (Co), ruthenium (Ru), palladium (Pd), platinum (Pt), manganese (Mn), tungsten nitride (WN), titanium nitride (TiN), tantalum nitride (TaN), molybdenum nitride (MoN), tungsten silicide (WSi), titanium silicide (TiSi₂), other suitable conductive materials, or combination thereof. The source structure 320 and the drain structure 325 may be formed by suitable photolithography processes, deposition processes, and/or etching processes.

In some embodiments, the etching process may include dry etching, wet etching, RIE, and/or other suitable processes. In some embodiments, the photolithography processes include photoresist coating (e.g., spin-on coating), soft baking, mask aligning, exposure, post-exposure baking, developing the photoresist, rinsing, and drying (e.g., hard baking). In other embodiments, the photolithography processes may be implemented or replaced by other suitable methods, such as maskless photolithography, electron-beam writing, and ion-beam writing.

In some embodiments, the deposition processes may include physical vapor deposition (PVD) process, CVD process, coating process, other suitable processes, or combination thereof. The PVD process may include sputter process, evaporation process, and pulsed laser deposition process. The CVD process may include LPCVD, LTCVD, RTCVD, PECVD, HDPCVD, MOCVD, remote plasma CVD (RPCVD) process, atomic layer deposition (ALD) process, plating process, other suitable processes, and/or combination thereof.

Please refer to FIG. 3C, a gate 330 is formed on the gate stack 310. The material of gate 330 may include but not limit to: Al, Cu, Au, Ag, W, Ti, Ta, Ni, Co, Ru, Pd, Pt, Mn, WN, TiN, TaN, MoN, WSi, TiSi₂, other suitable conductive materials, or combination thereof. The gate 330 may be formed by suitable photolithography processes, deposition processes, and/or etching processes. In some embodiments, various different formation sequences may be used to form the source structure 320, the drain structure 325, and the gate 330.

In some embodiments, the etching process may include dry etching, wet etching, RIE, and/or other suitable processes. In some embodiments, the photolithography processes include photoresist coating (e.g., spin-on coating), soft baking, mask aligning, exposure, post-exposure baking, developing the photoresist, rinsing, and drying (e.g., hard baking). In other embodiments, the photolithography processes may be implemented or replaced by other suitable methods, such as maskless photolithography, electron-beam writing, and ion-beam writing.

In some embodiments, the deposition processes may include physical vapor deposition (PVD) process, CVD process, coating process, other suitable processes, or combination thereof. The PVD process may include sputter process, evaporation process, and pulsed laser deposition process. The CVD process may include LPCVD, LTCVD, RTCVD, PECVD, HDPCVD, MOCVD, RPCVD, ALD, plating, other suitable processes, and/or combination thereof.

In semiconductor device 300, the barrier layer 140 under the gate 330 and the first epitaxial layer 220, the second epitaxial layer 230, and the third epitaxial layer 240 within the gate stack 310 form a thyristor.

As described above, in semiconductor device 300, the area under the gate stack 310 has no 2DEG due to the band bending. Therefore, it is necessary to modify the energy band by applying a positive voltage to the gate 330 to make the 2DEG reappear. As a result, the channel from the source structure 320 to the drain structure 325 formed by the two-dimensional electron gas reappears, and the semiconductor device 300 is also turned on. Since a positive voltage applied to the gate is needed for semiconductor device 300 to turn on, the threshold voltage (Vth) of semiconductor device 300 is greater than 0. Therefore, the semiconductor device 300 is an enhancement-mode device that is normally-off.

In the conventional enhancement-mode p-GaN HEMT, there is only a single layer of p-GaN below the gate, thus the positive voltage applied to the gate can effectively affect the energy band below the p-GaN. As a result, only a lower positive gate voltage is required to make the quantum well and 2DEG reappear. Therefore, although the threshold voltage of the conventional enhancement-mode p-GaN HEMT is greater than 0 V, the threshold voltage is still difficult to exceed 1.5V.

However, as described above, in semiconductor device 300, there is a thyristor below the gate 330. When a positive voltage is applied to the gate 330, the pn structure and the np structure within the thyristor will produce a voltage drop and consume the gate voltage. Therefore, a larger voltage is required to affect the energy band under the thyristor. In other words, due to the presence of the thyristor, a higher positive voltage needs to be applied to the gate to modify the energy band and make 2DEG reappear. As a result, the semiconductor device 300 with the thyristor has a greater threshold voltage.

In addition, since the presence of the thyristor can make the entire gate region of the semiconductor device 300 sustain a higher voltage, the semiconductor device 300 has a larger range of operating voltage. As a result, the drain current (Id) can be increased by increasing the gate voltage. Additionally, under the same gate voltage, the semiconductor device 300 can also have higher reliability.

In some embodiments, the contact between the gate 330 and the gate stack 310 is an Ohmic contact. In some other embodiments, the contact between the gate 330 and the gate stack 310 is a Schottky contact. In the embodiment of the Schottky contact, since the Schottky contact has the effect of a diode, an additional voltage drop is generated, and therefore the semiconductor device 300 has a greater threshold voltage.

In the embodiment that the material of the barrier layer 140 is aluminum gallium nitride (AlₓGa₁₋ₓN), the threshold voltage can be adjusted by changing the aluminum mole ratio or the thickness of the barrier layer 140. The increase of the aluminum mole ratio or the increase of the thickness of the barrier layer 140 will enhance the polarization effect of the semiconductor device 300 and therefore increase 2DEG concentration. As a result, the drain current (Id) of the semiconductor device 300 can be increased, and therefore the on-resistance (Ron) of the semiconductor device 300 can be reduced. Although the increase of the aluminum mole ratio or the increase of the thickness of the barrier layer 140 will reduce the threshold voltage (Vth) at the same time, since the semiconductor device 300 has a large threshold voltage, a little bit of the threshold voltage can be sacrificed to exchange a higher channel current while maintaining a sufficiently high threshold voltage.

In some embodiments, since the gate stack 310 (including the first epitaxial layer 220, the second epitaxial layer 230, and the third epitaxial layer 240) is formed by epitaxy technology, it has interfaces with better quality. In addition, since the gate stack 310 has a larger thickness, the etching process can be better controlled, and therefore the influence of the etching process on the barrier layer 140 can be reduced. In this way, the semiconductor device 300 has higher reliability.

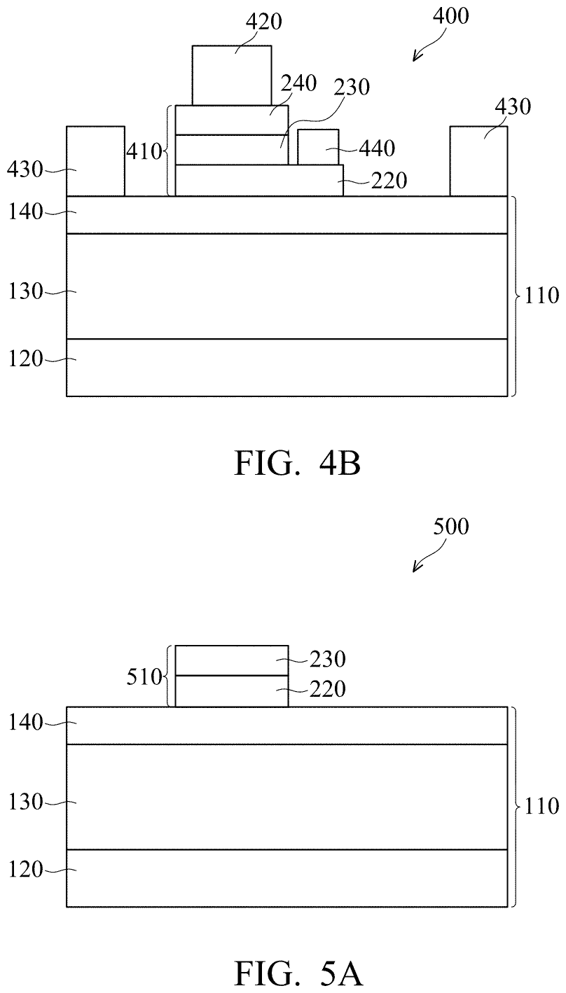

Following the process of FIG. 2, FIG. 4A shows the cross-sectional view of the intermediate stage for forming a semiconductor device 400 by utilizing the semiconductor structure 100, in accordance with some embodiments of the present disclosure. For example, the semiconductor device 400 may be formed in a second region of the semiconductor structure 100. The semiconductor device 400 may be a thyristor. In FIG. 4A, an epitaxial stack 410 is formed from the epitaxial structure 210. The epitaxial stack 410 comprises patterned first epitaxial 220, patterned second epitaxial layer 230, and patterned third epitaxial layer 240. The patterned first epitaxial layer 220 is larger than the patterned second epitaxial layer 230 and patterned third epitaxial layer 240. The patterned first epitaxial layer 220 can be divided into a first portion that is covered by the second epitaxial layer 230 and the third epitaxial layer 240 formed above, and a second portion that is not covered by the second epitaxial layer 230 and the third epitaxial layer 240. Some portions of the epitaxial structure 210 can be removed by patterning process to form the epitaxial stack 410 and exposed the portion of barrier layer 140 that is not covered by the epitaxial stack 410. The patterning process includes suitable photolithography processes and etching processes. The process for forming the epitaxial stack 410 is similar to the process for forming the gate stack 310, and in order to simplify the description, it will not be repeated herein.

Please refer to FIG. 4B, an anode 420 is formed on the third epitaxial layer 240 of the epitaxial stack 410, a cathode 430 is formed on the barrier layer 140, and a gate 440 is formed on the second portion of the first epitaxial layer 220, wherein the second portion is not covered by the second epitaxial layer 230 and the third epitaxial layer 240. The cathode 430 is disposed in a manner surrounding the anode 420 (and therefore equivalent to surrounding the epitaxial stack 410). The anode 420, the cathode 430, and the gate 440 may include similar materials to the source structure 320, the drain structure 325, and/or the gate 330, and in order to simplify the description, it will not be repeated herein.

The anode 420, the cathode 430, and the gate 440 may be formed by suitable photolithography processes, deposition processes, and/or etching processes. The processes for forming the anode 420, the cathode 430, and the gate 440 are similar to the processes for forming the source structure 320, the drain structure 325, and/or the gate 330, and in order to simplify the description, it will not be repeated herein. In some embodiments, various different formation sequences may be used to form the anode 420, the cathode 430, and the gate 440.

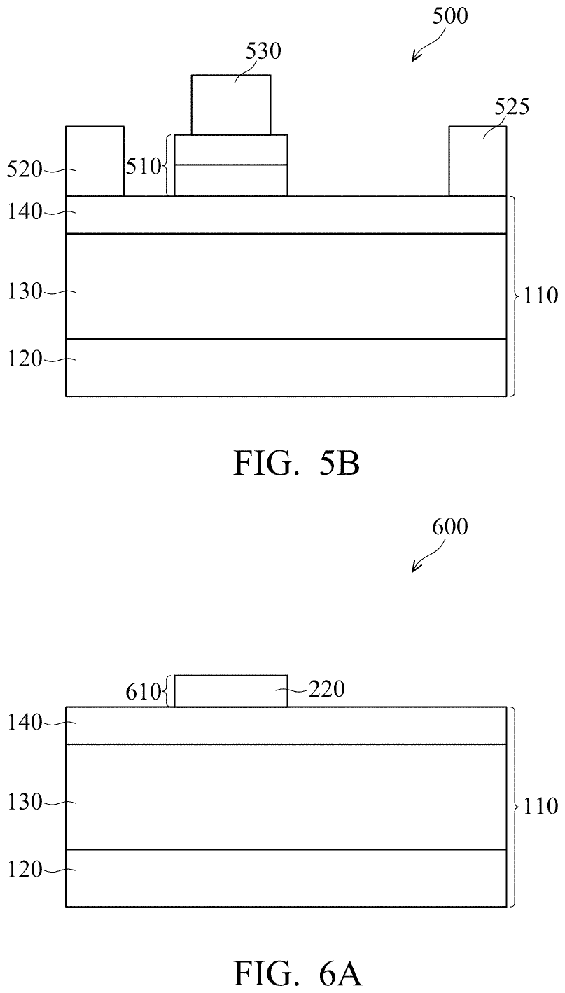

Following the process of FIG. 2, FIG. 5A shows the cross-sectional view of the intermediate stage for forming a semiconductor device 500 by utilizing the semiconductor structure 100, in accordance with some embodiments of the present disclosure. For example, the semiconductor device 500 may be formed in a third region of the semiconductor structure 100. The semiconductor device 500 may be a HEMT. In FIG. 5A, a gate stack 510 is formed from the epitaxial structure 210. The gate stack 510 comprises patterned first epitaxial layer 220 and patterned second epitaxial layer 230, wherein the third epitaxial layer 240 is removed. Some portions of the epitaxial structure 210 can be removed by patterning process to form the gate stack 510 and exposed the portion of barrier layer 140 that is not covered by the gate stack 510. The patterning process includes suitable photolithography processes and etching processes. The processes for forming the gate stack 510 are similar to the processes for forming the gate stack 310, and in order to simplify the description, it will not be repeated herein.

Similar to the gate stack 310, after forming the gate stack 510, the area not covered by the gate stack 510 is no longer affected by the band bending caused by the epitaxial structure 210. Therefore, the quantum well reappears, and 2DEG as the channel also appears. However, in the area under the gate stack 510, due to the band bending caused by the gate stack 510, there is still no quantum well and 2DEG.

Please refer to FIG. 5B, a source structure 520 and a drain structure 525 are formed on the barrier layer 140, and the gate 530 is formed on the gate stack 510. The source structure 520, drain structure 525, and the gate 530 may include similar materials to the source structure 320, the drain structure 325, and/or the gate 330, and in order to simplify the description, it will not be repeated herein.

The source structure 520, drain structure 525, and the gate 530 may be formed by suitable photolithography processes, deposition processes, and/or etching processes. The processes for forming the source structure 520, drain structure 525, and the gate 530 are similar to the processes for forming the source structure 320, the drain structure 325, and/or the gate 330, and in order to simplify the description, it will not be repeated herein. In some embodiments, various different formation sequences may be used to form the source structure 320, the drain structure 325, and the gate 330.

As described above, in semiconductor device 500, the area under the gate stack 510 does not have 2DEG due to the band bending. Therefore, it is requires to apply positive voltage on the gate 530 to modify the energy band to make 2DEG reappear. Accordingly, like the semiconductor device 300, the semiconductor device 500 is also an enhancement-mode device with a threshold voltage (Vth) greater than 0. In semiconductor device 500, the first epitaxial layer 220 and the second epitaxial layer 230 within the gate stack 510 form a PN junction. When a positive voltage is applied to the gate 530, the n-p (second epitaxial layer 230—first epitaxial layer 220) structure within the gate stack 510 will form a depletion region and consume the gate voltage. Therefore, it is required a larger voltage to affect the energy band under the gate stack 510. It means that since the existence of the PN junction in the gate stack 510, it is necessary to apply a larger positive voltage to the gate to modify the energy band and make 2DEG reappear. As a result, the semiconductor device 500 with the PN junction has a greater threshold voltage. It should be noted that, compared with the semiconductor device 500, the semiconductor device 300 has a larger threshold voltage (Vth).

In some embodiments, the contact between the gate 530 and the gate stack 510 is an Ohmic contact. In some other embodiments, the contact between the gate 530 and the gate stack 510 is a Schottky contact. In the embodiment of the Schottky contact, since the Schottky contact has the effect of a diode, an additional voltage drop is generated, and therefore the semiconductor device 500 has a greater threshold voltage.

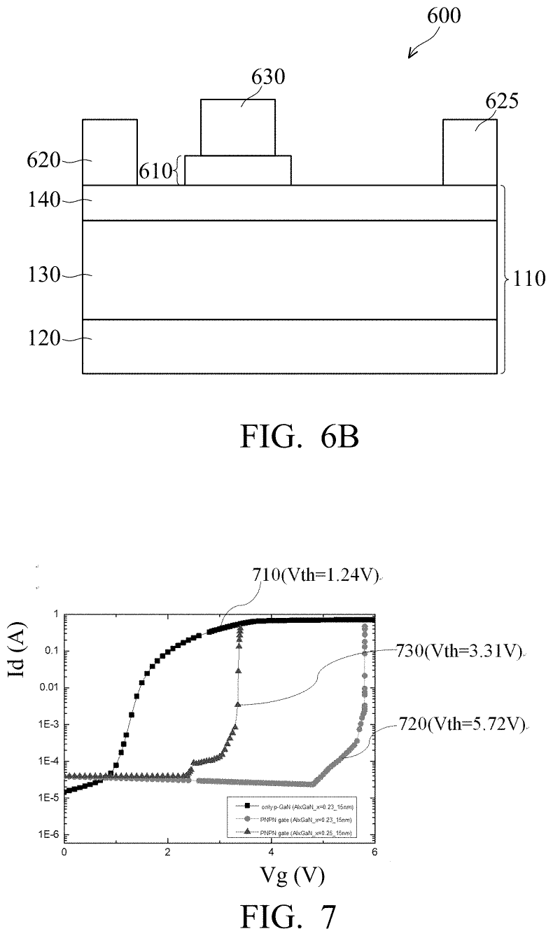

Following the process of FIG. 2, FIG. 6A shows the cross-sectional view of the intermediate stage for forming a semiconductor device 600 by utilizing the semiconductor structure 100, in accordance with some embodiments of the present disclosure. For example, the semiconductor device 600 may be formed in a fourth region of the semiconductor structure 100. The semiconductor device 600 may be a HEMT. In FIG. 6A, a gate stack 610 is formed from the epitaxial structure 210. The gate stack 610 comprises patterned first epitaxial layer 220, wherein the second epitaxial layer 230 and the third epitaxial layer 240 are removed. Some portions of the epitaxial structure 210 can be removed by patterning process to form the gate stack 610 and exposed the portion of barrier layer 140 that is not covered by the gate stack 610. The patterning process includes suitable photolithography processes and etching processes. The processes for forming the gate stack 610 are similar to the processes for forming the gate stack 310, and in order to simplify the description, it will not be repeated herein.

Similar to the gate stack 310, after forming the gate stack 610, the area not covered by the gate stack 610 is no longer affected by the band bending caused by the epitaxial structure 210. Therefore, the quantum well reappears, and 2DEG as the channel also appears. However, in the area under the gate stack 610, due to the band bending caused by the gate stack 610, there is still no quantum well and 2DEG.

Please refer to FIG. 6B, a source structure 620 and a drain structure 625 are formed on the barrier layer 140, and the gate 630 is formed on the gate stack 610. The source structure 620, drain structure 625, and the gate 630 may include similar materials to the source structure 320, the drain structure 325, and/or the gate 330, and in order to simplify the description, it will not be repeated herein.

The source structure 620, drain structure 625, and the gate 630 may be formed by suitable photolithography processes, deposition processes, and/or etching processes. The processes for forming the source structure 620, drain structure 625, and the gate 630 are similar to the processes for forming the source structure 320, the drain structure 325, and/or the gate 330, and in order to simplify the description, it will not be repeated herein. In some embodiments, various different formation sequences may be used to form the source structure 620, the drain structure 625, and the gate 630.

As described above, in semiconductor device 600, the area under the gate stack 610 does not have 2DEG due to the band bending. Therefore, it is requires to apply positive voltage on the gate 630 to modify the energy band to make 2DEG reappear. Accordingly, like the semiconductor device 300, the semiconductor device 600 is also an enhancement-mode device with a threshold voltage (Vth) greater than 0.

However, as described above, since the semiconductor device 600 may be a conventional enhancement-mode p-GaN HEMT, there is only the first epitaxial layer 220 (e.g. p-GaN) under the gate 630. Therefore, the positive voltage applied on the gate 630 can effectively affect the energy band under the first epitaxial layer 220. In this way, only a lower positive gate voltage is required to make the quantum well and 2DEG reappear. Therefore, although the threshold voltage of the semiconductor device 600 is greater than 0V, it is still difficult to be greater than 1.5V.

In some embodiments, the epitaxial structure 210 can be completely removed, and the gate can be directly formed on the barrier layer. As a result, a conventional depletion-mode HEMT can be formed. It should be noted that, by using the semiconductor structure 100 with the epitaxial structure 210, the semiconductor device 300, the semiconductor device 500, the semiconductor device 600 and the conventional depletion-mode HEMT can be formed through the same photomask. In addition, by using the semiconductor structure 100 with the epitaxial structure 210, various semiconductor devices including the semiconductor device 300, the semiconductor device 400, the semiconductor device 500, and the semiconductor device 600 can be formed in different regions on the same wafer.

FIG. 7 shows the simulation characteristic curves of drain current-gate voltage (Id-Vg) of the semiconductor devices, in accordance with some embodiments of the present disclosure. The curve 710 represents a conventional enhancement-mode p-GaN HEMT, such as the semiconductor device 600 (FIG. 6B). The curve 720 represents a HEMT with a thyristor below the gate, such as the semiconductor device 300 (FIG. 3C). The curve 730 represents the semiconductor device 300 in which the aluminum mole ratio of the barrier layer is increased. Wherein in curve 710, the barrier layer of the device is Al_{0.23}Ga_{0.77}N, in curve 720, the barrier layer of the device is Al_{0.23}Ga_{0.77}N, and in curve 730, the barrier layer of the device is Al_{0.25}Ga_{0.75}N.

As shown by the curve 710 and the curve 720, the threshold voltage (Vth) of the semiconductor device 600 is about 1.24V, and the threshold voltage (Vth) of the semiconductor device 300 with a thyristor is about 5.72V. Therefore, it can be found that the HEMT with a thyristor can have a much larger threshold voltage. As shown by the curve 730, the semiconductor device 300 with an increased aluminum mole ratio has a lower threshold voltage (about 3.31V). Therefore, it can be found that the HEMT with a thyristor can adjust the threshold voltage by changing the aluminum mole ratio, and maintain a larger threshold voltage while increasing the aluminum mole ratio.

The present disclosure provides a semiconductor device for enhancement-mode high electron mobility transistor (HEMT). By disposing a thyristor below the gate, the HEMT can have a larger threshold voltage, a larger range of operating voltage, and better reliability. In addition, since the large threshold voltage, a higher channel current can be obtained by sacrificing a little bit of threshold voltage while maintaining a sufficiently high threshold voltage. Since the large threshold voltage, the semiconductor device provided by the present disclosure can prevent false turn on caused by surge, electromagnetic interference, noise, or voltage disturbance.

The present disclosure provides another semiconductor device for enhancement-mode high electron mobility transistor (HEMT). By disposing a PN junction below the gate, the HEMT can have a larger threshold voltage, a larger range of operating voltage, and better reliability. Since the large threshold voltage, this semiconductor device can also prevent false turn on caused by surge, electromagnetic interference, noise, or voltage disturbance.

The present disclosure provides a thyristor, this thyristor can be manufactured be utilizing the epitaxial structure used for manufacturing the enhancement-mode HEMT described above. As a result, the complexity and cost for forming different electronic components on the same wafer can be reduced.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A semiconductor device, comprising:
a substrate;
a buffer layer, disposed on the substrate;
a barrier layer, disposed on the buffer layer;
a drain, a source, and a gate stack, disposed on the barrier layer, wherein the gate stack comprises a first epitaxial layer over the barrier layer and a second epitaxial layer over the first epitaxial layer; and
a gate, disposed on the gate stack.

2. The semiconductor device as claimed in claim 1, wherein the first epitaxial layer is p-type-doped GaN (p-GaN), and the second epitaxial layer is n-type-doped GaN (n-GaN).

3. The semiconductor device as claimed in claim 1, wherein the gate stack further comprises a third epitaxial layer disposed on the second epitaxial layer.

4. The semiconductor device as claimed in claim 3, wherein a least a part of the barrier layer, the first epitaxial layer, the second epitaxial layer, and the third epitaxial layer form a thyristor.

5. The semiconductor device as claimed in claim 3, wherein the first epitaxial layer is p-GaN, the second epitaxial layer is n-GaN, and the third epitaxial layer is p-GaN.

6. The semiconductor device as claimed in claim 1, wherein an interface between the gate and the gate stack is a Schottky contact.

7. The semiconductor device as claimed in claim 1, wherein an interface between the gate and the gate stack is an Ohmic contact.

8. A semiconductor device, comprising:
a substrate;
a buffer layer, disposed on the substrate;
a barrier layer, disposed on the buffer layer;
a stack structure, disposed on the barrier layer;
an anode, disposed on the stack structure; and
a cathode, disposed on the barrier layer, the cathode surrounding the stack structure and the anode.

9. The semiconductor device as claimed in claim 8, wherein the stack structure comprises a first epitaxial layer disposed on the barrier layer, a second epitaxial layer disposed on a first portion of the first epitaxial layer, and a third epitaxial layer disposed on the second epitaxial layer.

10. The semiconductor device as claimed in claim 9, further comprising a gate connected to a second portion of the first epitaxial layer.

11. The semiconductor device as claimed in claim 9, wherein the first epitaxial layer is p-type-doped GaN (p-GaN), the second epitaxial layer is n-type-doped GaN (n-GaN), and the third epitaxial layer is p-GaN.

12. A method of forming a semiconductor structure, comprising:
forming a buffer layer on a substrate;
forming a barrier layer on the buffer layer;
forming an epitaxial structure on the barrier layer, wherein the epitaxial structure comprises a first epitaxial layer, a second epitaxial layer over the first epitaxial layer, and a third epitaxial layer over the second epitaxial layer; and
forming a first semiconductor device in a first region of the semiconductor structure, wherein the formation of the first semiconductor device comprises:
performing a first etching process on the epitaxial structure to form a first gate stack from the epitaxial structure and to expose the portion of the barrier layer uncovered by the first gate stack;
forming a first source and a first drain on the barrier layer; and
forming a first gate on the first gate stack.

13. The method as claimed in claim 12, wherein the first epitaxial layer is p-type-doped GaN (p-GaN), the second epitaxial layer is n-type-doped GaN (n-GaN), and the third epitaxial layer is p-GaN.

14. The method as claimed in claim 13, wherein the barrier layer and the first epitaxial layer, the second epitaxial layer, and the third epitaxial layer within the first gate stack form a thyristor.

15. The method as claimed in claim 12, further comprising forming a second semiconductor device in a second region of the semiconductor structure, wherein the formation of the second semiconductor device comprises:
performing a second etching process on the epitaxial structure to form a second stack from the epitaxial structure and to expose the portion of the barrier layer uncovered by the second stack;
forming an anode on the second stack;
forming a cathode on the barrier layer, wherein the cathode surrounds the second stack and the anode; and
forming a second gate on the first epitaxial layer of the second stack.

16. The method as claimed in claim 12, further comprising forming a third semiconductor device in a third region of the semiconductor structure, wherein the formation of the third semiconductor device comprises:
performing a third etching process on the epitaxial structure to remove the third epitaxial layer, to form a third gate stack from the first epitaxial layer and the second epitaxial layer of the epitaxial structure, and to expose the portion of the barrier layer uncovered by the third gate stack;
forming a third source and a third drain on the barrier layer; and
forming a third gate on the third gate stack.

17. The method as claimed in claim 12, further comprising forming a fourth semiconductor device in a fourth region of the semiconductor structure, wherein the formation of the fourth semiconductor device comprises:
performing a fourth etching process on the epitaxial structure to remove the third epitaxial layer and the second epitaxial layer, to form a fourth gate stack from the first epitaxial layer of the epitaxial structure, and to expose the portion of the barrier layer uncovered by the fourth gate stack;
forming a fourth source and a fourth drain on the barrier layer; and
forming a fourth gate on the fourth gate stack.
